(19) United States
(12) Patent Application Publication
(10) Pub. No.: US 2016/0181997 A1
(43) Pub. Date: Jun. 23, 2016

(54) SIGNAL AMPLIFYING CIRCUIT

(71) Applicant: uPI semiconductor corp., Zhubei City (TW)

(72) Inventor: Wen-Sheng Lin, Zhubei City (TW)

(21) Appl. No.: 14/707,081

(22) Filed: May 8, 2015

(30) Foreign Application Priority Data
Dec. 18, 2014 (TW) 103144346

(51) Int. Cl. H03F 3/45

(52) U.S. Cl. CPC H03F 3/45076; H03F 2200/471; H03F 2200/21; H03F 2203/45112

(57) ABSTRACT

A signal amplifying circuit includes an operational amplifying module, a level adjusting module, and a voltage module. The operational amplifying module has a first input terminal, a second input terminal, and an output terminal The output terminal outputs a single-ended output signal having a level of zero. The level adjusting module has a control node and coupled to the first input terminal and the second input terminal respectively. The level adjusting module receives a first input signal and a second input signal of a pair of differential input signals respectively. The first input signal and the second input signal both have a first level but have inversed phases. The voltage module is coupled to the control node and used to provide a voltage signal having a second level to the control node.

### BACKGROUND OF THE INVENTION

1. Field of the Invention

The invention relates to a signal amplifying circuit; in particular, to a signal amplifying circuit having simple circuit structure and capable of saving DC power supply.

2. Description of the Prior Art

In general, no matter the feature phone, the smart phone, or other electronic apparatuses, there is usually an audio signal processing circuit disposed in them to perform appropriate processes on audio signals.

Please refer to FIG. 1. FIG. 1 illustrates a function block diagram of a conventional audio signal processing circuit. As shown in FIG. 1, the conventional audio signal processing circuit 100 includes a digital-to-analog converter (DAC) 110, an analog mixer/router 120, a headphone output amplifier 130, an earpiece output amplifier 132, and a line out amplifier 134.

When the DAC 110 receives a digital audio data signal S1, the DAC 110 converts the digital audio data signal S1 into an analog audio data signal S2 and then transmits the analog audio data signal S2 to the analog mixer/router 120.

The analog mixer/router 120 can not only receive the analog audio data signal S2 from the DAC 110, but also receive a line in audio signal S3. The analog mixer/router 120 can generate different audio input signals S4˜S6 by combining or routing the analog audio data signal S2 and the line in audio signal S3 respectively based on different requirements, and then transmit these audio input signals S4˜S6 to the headphone output amplifier 130, the earpiece output amplifier 132, and the line out amplifier 134 respectively. Then, the headphone output amplifier 130, the earpiece output amplifier 132, and the line out amplifier 134 will perform the audio signal amplifying process to generate a headphone audio output signal AS4, an earpiece audio output signal AS5, and a line in audio output signal AS6 respectively. Then, the headphone output amplifier 130, the earpiece output amplifier 132, and the line out amplifier 134 will output the headphone audio output signal AS4, the earpiece audio output signal AS5, and the line in audio output signal AS6 respectively.

Then, please refer to FIG. 2. FIG. 2 illustrates a circuit schematic diagram of the conventional output amplifier cooperated with complicated signal voltage level adjusting circuit. As shown in FIG. 2, two receiving terminals of the conventional output amplifier 410 receive a first input signal Vinp and a second input signal Vinn respectively, and the first input signal Vinp and the second input signal Vinn are a pair of differential input signals having the same DC voltage level and inversed phases. An output terminal of the output amplifier 410 outputs a single-ended output signal Vout. Two voltage control terminals of the output amplifier 410 are coupled to the voltage signals VDD and VEE respectively. In order to adjust the DC voltage level of the single-ended output signal Vout outputted by the output amplifier 410, the output amplifier 410 has to be cooperated with a signal voltage level adjusting circuit 540b having a complicated circuit structure to generate a level shift of (current Ios*resistance R) on the DC voltage level of the single-ended output signal Vout outputted by the output amplifier 410. It makes the circuit structure of the conventional signal output amplifying circuit become more complicated, not only occupy larger area but also increase the cost.

### SUMMARY OF THE INVENTION

Therefore, the invention provides a signal amplifying circuit to solve the above-mentioned problems occurred in the prior arts.

An embodiment of the invention is a signal amplifying circuit. In this embodiment, the signal amplifying circuit includes an operational amplifying module, a level adjusting module, and a voltage module. The operational amplifying module has a first input terminal, a second input terminal, and an output terminal The output terminal outputs a single-ended output signal having a level of zero. The level adjusting module has a control node and coupled to the first input terminal and the second input terminal respectively. The level adjusting module receives a first input signal and a second input signal of a pair of differential input signals respectively. The first input signal and the second input signal both have a first level but have inversed phases. The voltage module is coupled to the control node and used to provide a voltage signal having a second level to the control node.

In an embodiment of the invention, the operational amplifying module further has a first voltage control terminal and a second voltage control terminal, and the first voltage control terminal and the second voltage control terminal are used to receive a first voltage signal and a second voltage signal respectively.

In an embodiment of the invention, the first voltage signal received by the first voltage control terminal has the first level the same with the first input signal and the second input signal.

In an embodiment of the invention, the second voltage signal received by the second voltage control terminal has the second level the same with the voltage signal.

In an embodiment of the invention, the second voltage control terminal is coupled to the voltage module and the second voltage control terminal receives the voltage signal having the second level provided by the voltage module.

In an embodiment of the invention, the voltage signal is a negative voltage signal.

In an embodiment of the invention, the level adjusting module includes a first impedance unit, a second impedance unit, a third impedance unit, and a four impedance unit having the same impedance value, the second impedance unit and the third impedance unit are coupled to the control node, the first impedance unit and the second impedance unit are coupled to a first node, the third impedance unit and the four impedance unit are coupled to a second node, the first input signal and the second input signal are received by the first impedance unit and the four impedance unit respectively.

In an embodiment of the invention, the first input signal at the first node and the second input signal at the second node both have a third level and the third level is an average of the first level and the second level.

In an embodiment of the invention, the first input terminal of the operational amplifying module is coupled to the first node and the second input terminal of the operational amplifying module is coupled to the second node, the operational amplifying module obtains the single-ended output signal having the level of zero according to the third level that the first input signal at the first node and the second input signal at the second node have.

In an embodiment of the invention, the signal amplifying circuit further includes a fifth impedance unit. The fifth impedance unit is coupled between the first node and the output terminal of the operational amplifying module.

Another embodiment of the invention is also a signal amplifying circuit. In this embodiment, the signal amplifying circuit includes an operational amplifying module, a level adjusting module, and a voltage module. The operational amplifying module has a first input terminal, a second input terminal, an output terminal, a first voltage control terminal, and a second voltage control terminal. The first voltage control terminal and the second voltage control terminal receive a first voltage signal and a second voltage signal respectively, and the output terminal outputs a single-ended output signal having a level of zero. The level adjusting module has a control node. The level adjusting module is coupled to the first input terminal and the second input terminal respectively. The level adjusting module receives a first input signal and a second input signal of a pair of differential input signals respectively. The first input signal and the second input signal both have a first level but have inversed phases. The voltage module is coupled to the control node and used to provide a voltage signal having a second level to the control node. The first voltage signal received by the first voltage control terminal has the first level and the second voltage signal received by the second voltage control terminal has the second level.

Compared to the prior arts, without any additional complicated signal voltage level adjusting circuit, the signal amplifying circuit of the invention only needs a voltage dividing design of impedance units having the same impedance value to convert the DC differential input signal into the DC single-ended output signal. Therefore, when the signal amplifying circuit of the invention is coupled with subsequent circuits, the effect of saving DC power supply can be achieved.

The advantage and spirit of the invention may be understood by the following detailed descriptions together with the appended drawings.

### BRIEF DESCRIPTION OF THE APPENDED DRAWINGS

FIG. 1 illustrates a functional block diagram of the conventional audio signal processing circuit.

FIG. 2 illustrates a circuit schematic diagram of the conventional output amplifier cooperated with complicated signal voltage level adjusting circuit.

FIG. 3 illustrates a functional block diagram of the signal amplifying circuit in an embodiment of the invention.

FIG. 4A and FIG. 4B illustrate schematic diagrams of the DC voltage levels of the first input signal and the second input signal respectively.

FIG. 4C and FIG. 4D illustrate schematic diagrams of the level-adjusted DC voltage levels of the first input signal and the second input signal respectively.

FIG. 4E illustrates a schematic diagram of the DC voltage level of the single-ended output signal.

FIG. 5 illustrates a detailed circuit schematic diagram of an embodiment of the signal amplifying circuit in FIG. 3.

FIG. 6A, FIG. 6B, and FIG. 6C illustrate the output signals having different waveforms outputted by the operational amplifying module respectively.

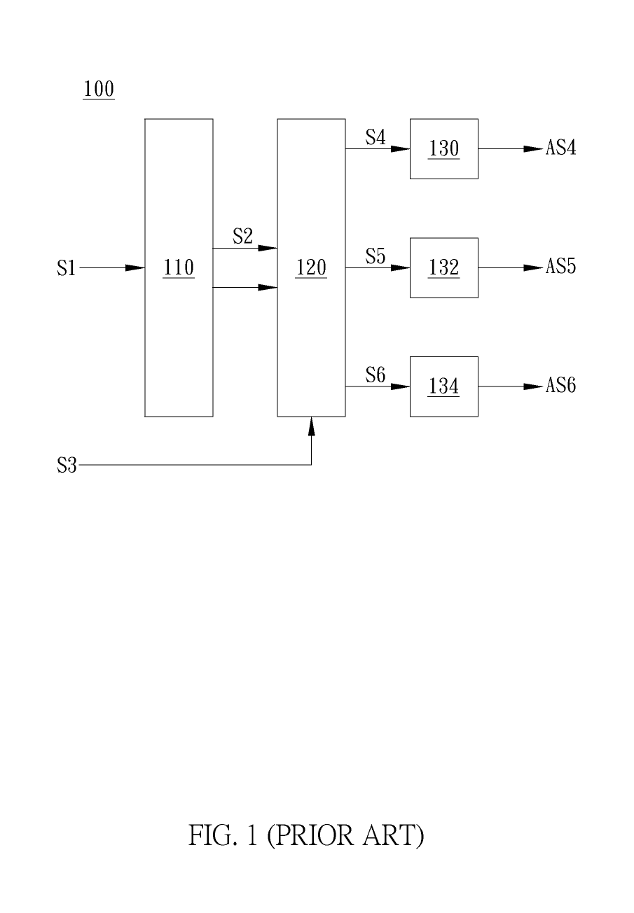

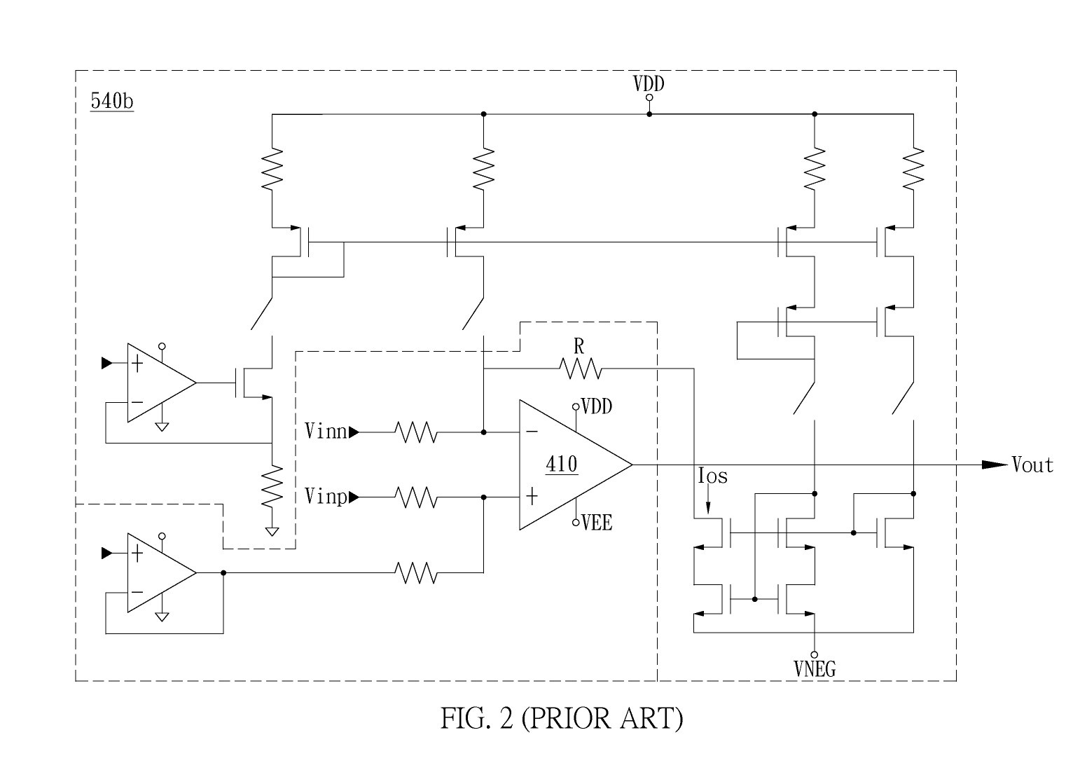

### DETAILED DESCRIPTION OF THE INVENTION

Exemplary embodiments of the present invention are referenced in detail now, and examples of the exemplary embodiments are illustrated in the drawings. Further, the same or similar reference numerals of the elements/components in the drawings and the detailed description of the invention are used on behalf of the same or similar parts. In the following embodiments, if an element is “connected” or “coupled” to another element, the element may be directly connected or coupled to the another element, or there may be any elements or specific materials (e.g., colloid or solder) disposed between the element and the another element.

A preferred embodiment of the invention is a signal amplifying circuit. In this embodiment, the signal amplifying circuit can be applied in an audio codec disposed in a power management integrated circuit (PMIC) or an independent audio codec to convert differential audio input signals into single-ended audio output signals having a level of zero, but not limited to this.

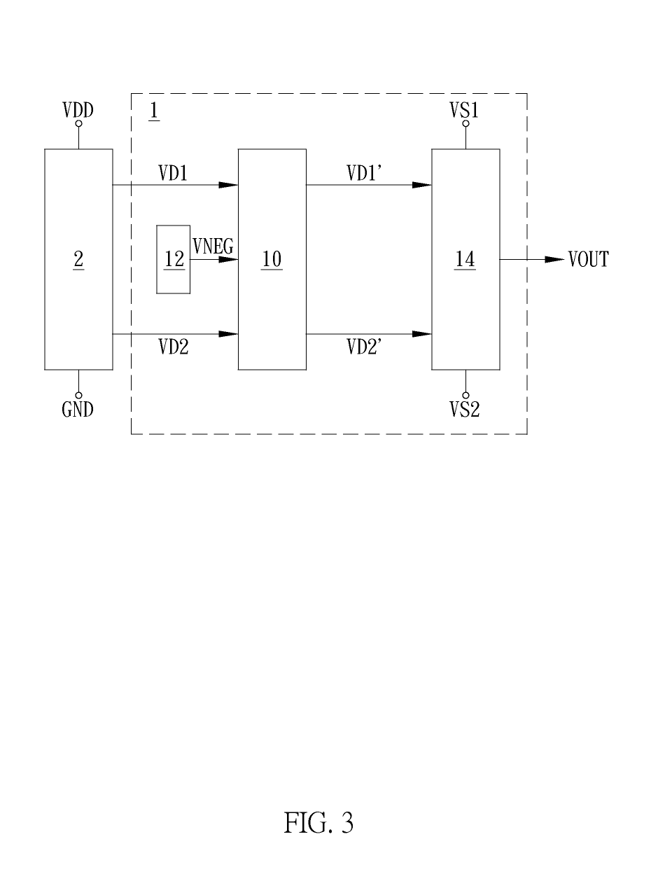

Please refer to FIG. 3. FIG. 3 illustrates a functional block diagram of the signal amplifying circuit in this embodiment. As shown in FIG. 3, the signal amplifying circuit 1 includes a level adjusting module 10, a voltage module 12, and an operational amplifying module 14. Wherein, the voltage module 12 is coupled to the level adjusting module 10; the level adjusting module 10 is coupled to the operational amplifying module 14. The operational amplifying module 14 is coupled to a first voltage signal VS1 and a second voltage signal VS2 respectively. In addition, the level adjusting module 10 is also coupled to a differential signal generating module 2. The differential signal generating module 2 is coupled to a work voltage VDD and a ground voltage GND respectively.

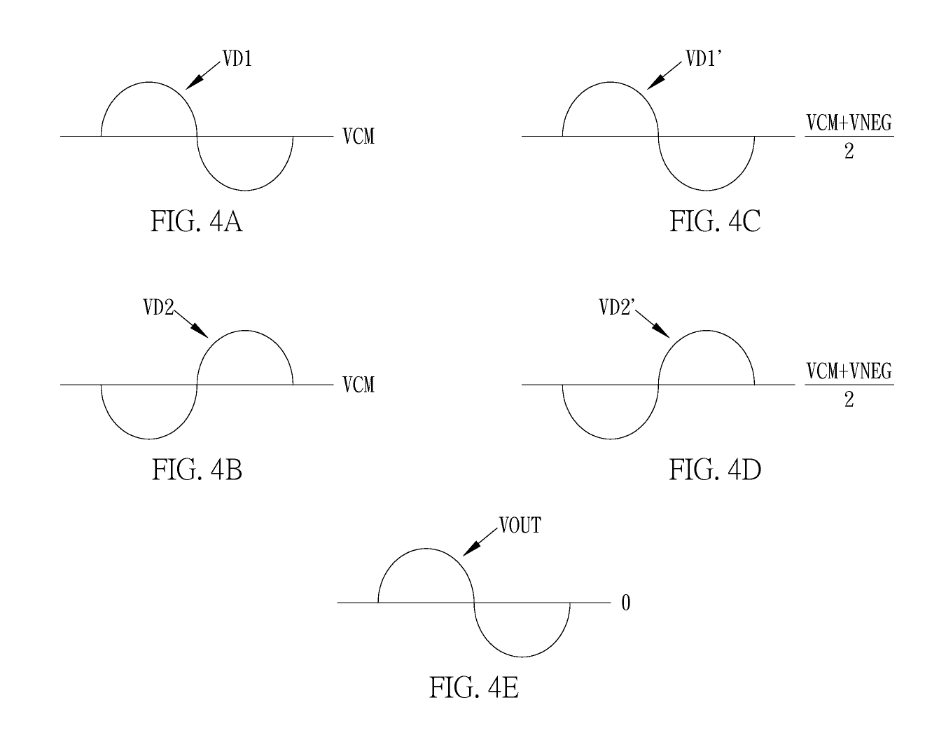

The differential signal generating module 2 generates a pair of differential signals including a first input signal VD1 and a second input signal VD2 and then outputs the first input signal VD1 and the second input signal VD2 to the level adjusting module 10 respectively. As shown in FIG. 4A and FIG. 4B, the first input signal VD1 and the second input signal VD2 have the same DC voltage level (namely a first level VCM) but have inversed phases. In fact, the waveform of the first input signal VD1 and the second input signal VD2 can be a sine wave as shown in FIG. 4A and FIG. 4B or any other waveforms without specific limitations.

In practical applications, the pair of differential signals can be a pair of analog differential audio signals, but not limited to this. The first level VCM of the first input signal VD1 and the second input signal VD2 can be an average of the work voltage VDD and the ground voltage GND coupled by the differential signal generating module 2 respectively. For example, if the work voltage VDD is 1.8 volts and the ground voltage GND is 0 volt, the first level VCM of the first input signal VD1 and the second input signal VD2 can be 0.9 volts, but not limited to this.

The voltage module 12 will provide a voltage signal VNEG to the level adjusting module 10. In practical applications, the second level of the voltage signal VNEG has a negative value, such as −0.9 volts; that is to say, the voltage signal VNEG is a negative voltage signal, but not limited to this.

The level adjusting module 10 receives the first input signal VD1 and the second input signal VD2 from the differential signal generating module 2 and the voltage signal VNEG from the voltage module 12 respectively. The level adjusting module 10 also outputs the level adjusted first input signal VD1′ and second input signal VD2′ having a third level to the operational amplifying module 14 respectively.

In practical applications, the third level can be an average of the first level VCM and the second level VNEG. For example, as shown in FIG. 4C and FIG. 4D, the third level of the first input signal VD1′ and the second input signal VD2′ is ½(VCM+VNEG), but not limited to this.

When the operational amplifying module 14 receives the first input signal VD1′ and the second input signal VD2′, the operational amplifying module 14 subtracts the voltage level of the second input signal VD2′ from the voltage level of the first input signal VD1′. Since the first input signal VD1′ and the second input signal VD2′ have the same voltage level (namely the third level), the voltage level of a single-ended output signal VOUT outputted by the output terminal K of the operational amplifying module 14 is 0, as shown in FIG. 4E.

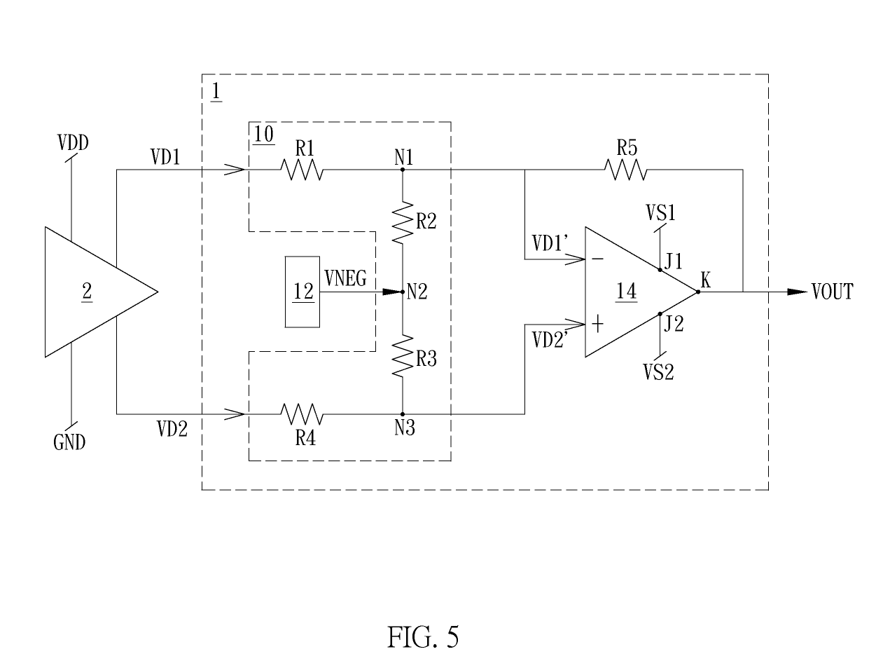

Then, please refer to FIG. 5. FIG. 5 illustrates a detailed circuit schematic diagram of an embodiment of the signal amplifying circuit in FIG. 3. As shown in FIG. 5, the level adjusting module 10 of the signal amplifying circuit 1 includes a first impedance unit R1, a second impedance unit R2, a third impedance unit R3, and a four impedance unit R4 having the same impedance value. Wherein, the first impedance unit R1 and the second impedance unit R2 are coupled to a first node N1; the second impedance unit R2 and the third impedance unit R3 are coupled to a second node N2; the third impedance unit R3 and the four impedance unit R4 are coupled to a third node N3; the first impedance unit R1 and the four impedance unit R4 are coupled to the differential signal generating module 2 respectively and the first impedance unit R1 and the four impedance unit R4 receive the first input signal VD1 and the second input signal VD2 from the differential signal generating module 2 respectively. The first input signal VD1 and the second input signal VD2 are a pair of differential signals having the same first level VCM and inversed phases. The voltage module 12 is coupled to the second node N2 between the second impedance unit R2 and the third impedance unit R3 and the voltage module 12 provides the voltage signal VNEG to the second node N2. In practical applications, the second level of the voltage signal VNEG has a negative value, such as −0.9 volts. That is to say, the voltage signal VNEG is a negative voltage signal, but not limited to this.

It should be noticed that the first impedance unit R1, the second impedance unit R2, the impedance unit R3, and the four impedance unit R4 of the level adjusting module 10 have the same impedance, and the first input signal VD1 and the second input signal VD2 received by the first impedance unit R1 and the four impedance unit R4 respectively have the same first level VCM; therefore, according to the voltage dividing theorem, the DC voltage level of the first input signal VD1′ at the first node N1 and the DC voltage level of the second input signal VD2′ at the third node N3 are both equal to ½(VCM+VNEG). In practical applications, the first impedance unit R1, the second impedance unit R2, the impedance unit R3, and the four impedance unit R4 can be resistors having the same resistance, but not limited to this.

For example, if the first level VCM is 0.9 volts and the second level VNEG is −0.9 volts, the DC voltage levels of the first input signal VD1′ and the second input signal VD2′ are both 0; if the first level VCM is 0.9 volts and the second level VNEG is −0.5 volts, the DC voltage levels of the first input signal VD1′ and the second input signal VD2′ are both 0.2 volts; other examples are all similar, so that they are not repeated here.

The operational amplifying module 14 has a first receiving terminal −, a second terminal +, an output terminal K, a first voltage control terminal J1, and a second voltage control terminal J2. Wherein, the first receiving terminal − is coupled between the first node N1 and the fifth impedance unit R5 to receive the first input signal VD1′; the second terminal + is coupled to the third terminal − to receive the second input signal VD2′; the first voltage control terminal J1 and the second voltage control terminal J2 are coupled to the first voltage signal VS1 and the second voltage signal VS2 respectively.

It should be noticed that, in this embodiment, the first voltage signal VS1 received by the first voltage control terminal J1 of the operational amplifying module 14 has the first level VCM the same with the first input signal VD1 and the second input signal VD2; the second voltage signal VS2 received by the second voltage control terminal J2 of the operational amplifying module 14 has the second level the same with the voltage signal VNEG.

In practical applications, the second voltage control terminal J2 of the operational amplifying module 14 can be not only coupled to the voltage module 12 and receive the voltage signal VNEG having the second level provided by the voltage module 12, but also coupled to an external power supply and receive the second voltage signal VS2 having the second level provided by the external power supply. It has no specific limitations.

The operational amplifying module 14 will obtain the DC voltage level of the output signal VOUT by subtracting the DC voltage level of the second input signal VD2′ from the DC voltage level of the first input signal VD1′. Since the DC voltage level of the first input signal VD1′ and the DC voltage level of the second input signal VD2′ are the same, the DC voltage level of the output signal VOUT obtained by the operational amplifying module 14 will be 0.

For example, if the DC voltage levels of the first input signal VD1′ and the second input signal VD2′ are both 0, the operational amplifying module 14 will subtract the DC voltage level of the second input signal VD2′ from the DC voltage level of the first input signal VD1′ to obtain the output signal VOUT having the DC voltage level of 0; if the DC voltage levels of the first input signal VD1′ and the second input signal VD2′ are both 0.2 volts, the operational amplifying module 14 will subtract the DC voltage level of the second input signal VD2′ from the DC voltage level of the first input signal VD1′ to obtain the output signal VOUT having the DC voltage level of 0.

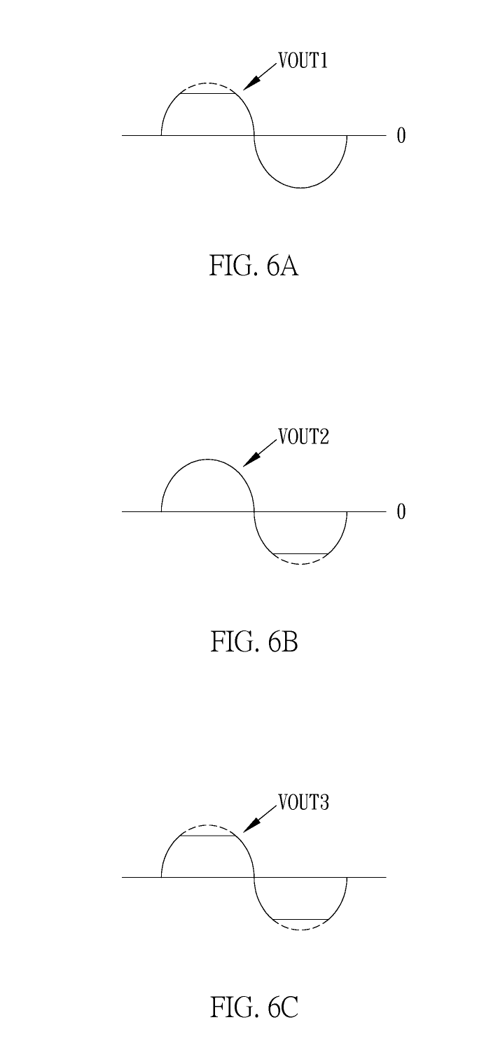

In practical applications, the output signal VOUT can be an analog single-ended audio signal, but not limited to this. The operational amplifying module 14 can adjust the waveform of the output signal VOUT according to the different DC voltage levels of the first voltage signal VS1 and the second voltage signal VS2. For example, if the DC voltage level of the first voltage signal VS1 is not equal to the first level VCM or the DC voltage level of the second voltage signal VS2 is not equal to the second level VNEG, then the output signal outputted by the output terminal K of the operational amplifying module 14 may have a waveform similar to the cut-out waveforms of the output signals VOUT1, VOUT2, and VOUT3 in FIG. 6A, FIG. 6B, and FIG. 6C respectively, but not limited to this.

Compared to the prior arts, without any additional complicated signal voltage level adjusting circuit, the signal amplifying circuit of the invention only needs a voltage dividing design of impedance units having the same impedance value to convert the DC differential input signal into the DC single-ended output signal. Therefore, when the signal amplifying circuit of the invention is coupled with subsequent circuits, the effect of saving DC power supply can be achieved.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A signal amplifying circuit, comprising:
an operational amplifying module having a first input terminal, a second input terminal, and an output terminal, wherein the output terminal outputs a single-ended output signal having a level of zero;
a level adjusting module having a control node, wherein the level adjusting module is coupled to the first input terminal and the second input terminal respectively, and the level adjusting module receives a first input signal and a second input signal of a pair of differential input signals respectively, the first input signal and the second input signal both have a first level but have inversed phases; and
a voltage module, coupled to the control node, for providing a voltage signal having a second level to the control node.

2. The signal amplifying circuit of claim 1, wherein the operational amplifying module further has a first voltage control terminal and a second voltage control terminal, and the first voltage control terminal and the second voltage control terminal are used to receive a first voltage signal and a second voltage signal respectively.

3. The signal amplifying circuit of claim 2, wherein the first voltage signal received by the first voltage control terminal has the first level the same with the first input signal and the second input signal.

4. The signal amplifying circuit of claim 2, wherein the second voltage signal received by the second voltage control terminal has the second level the same with the voltage signal.

5. The signal amplifying circuit of claim 2, wherein the second voltage control terminal is coupled to the voltage module and the second voltage control terminal receives the voltage signal having the second level provided by the voltage module.

6. The signal amplifying circuit of claim 1, wherein the voltage signal is a negative voltage signal.

7. The signal amplifying circuit of claim 1, wherein the level adjusting module comprises a first impedance unit, a second impedance unit, a third impedance unit, and a four impedance unit having the same impedance value, the second impedance unit and the third impedance unit are coupled to the control node, the first impedance unit and the second impedance unit are coupled to a first node, the third impedance unit and the four impedance unit are coupled to a second node, the first input signal and the second input signal are received by the first impedance unit and the four impedance unit respectively.

8. The signal amplifying circuit of claim 7, wherein the first input signal at the first node and the second input signal at the second node both have a third level and the third level is an average of the first level and the second level.

9. The signal amplifying circuit of claim 8, wherein the first input terminal of the operational amplifying module is coupled to the first node and the second input terminal of the operational amplifying module is coupled to the second node, the operational amplifying module obtains the single-ended output signal having the level of zero according to the third level that the first input signal at the first node and the second input signal at the second node have.

10. The signal amplifying circuit of claim 7, further comprising:
a fifth impedance unit, coupled between the first node and the output terminal of the operational amplifying module.

11. A signal amplifying circuit, comprising:
an operational amplifying module having a first input terminal, a second input terminal, an output terminal, a first voltage control terminal, and a second voltage control terminal, wherein the first voltage control terminal and the second voltage control terminal receive a first voltage signal and a second voltage signal respectively, and the output terminal outputs a single-ended output signal having a level of zero;
a level adjusting module having a control node, wherein the level adjusting module is coupled to the first input terminal and the second input terminal respectively, the level adjusting module receives a first input signal and a second input signal of a pair of differential input signals respectively, the first input signal and the second input signal both have a first level but have inversed phases; and
a voltage module, coupled to the control node, for providing a voltage signal having a second level to the control node,
wherein the first voltage signal received by the first voltage control terminal has the first level and the second voltage signal received by the second voltage control terminal has the second level.
